(19) United States
(12) Patent Application Publication
(10) Pub. No.: US 2022/0098042 A1
(43) Pub. Date: Mar. 31, 2022

(54) SYSTEM AND PROCESS FOR MANUFACTURING A GRAPHENE LAYER ON A SUBSTRATE

(71) Applicant: The 280 Company, Espoo (FI)

(72) Inventor: Filip SAARI, Espoo (FI)

(73) Assignee: The 280 Company, Espoo (FI)

(21) Appl. No.: 17/421,807

(22) PCT Filed: Mar. 17, 2020
(86) PCT No.: PCT/EP2020/057250

§ 371 Date: Jul. 9, 2021

(30) Foreign Application Priority Data
Mar. 18, 2019 (FI) 20195198

(51) Int. Cl. C01B 32/186; B32B 9/00; C23C 16/26

(52) U.S. Cl. CPC C01B 32/186; B82Y 30/00; C23C 16/26; B32B 9/00

(57) ABSTRACT

A manufacturing process for manufacturing a graphene layer on a substrate, includes providing a gaseous environment for chemical vapour deposition with a pressure in a range of 0.5-2 bar, the gaseous environment having a composition of hydrogen gas, a first inert gas, and a second gas in certain ratios; pre-heating the substrate to a first temperature; heating a first area of the substrate to a second temperature which is higher than the first temperature, wherein the first area has a first width that is less than 1 millimetre; allowing a graphene layer to form on the first area by chemical vapour deposition; allowing the first area to cool down; and repeating the above steps for a formation of a graphene layer on the substrate.

### TECHNICAL FIELD

The present disclosure relates generally to graphene materials; and more specifically, to a system and process for manufacturing a graphene layer on a substrate.

### BACKGROUND

Graphene is an allotrope of carbon that exists as a flat two-dimensional sheet of carbon atoms arranged on hexagonal lattice resembling a honeycomb. Since the discovery of graphene and the realization of its exceptional opto-electronic properties, there has been a rapid progress in the production of graphene materials employing various graphene production techniques to enable graphene's use in commercial applications. Graphene is increasingly used as a semiconductor material replacing traditionally used silicon and germanium because of its superior optical, thermal and electrical properties. The graphene is potentially used for novel applications in electronics like smartphone screens and electric vehicles. Furthermore, its multifunctionality makes graphene suitable for a wide spectrum of applications ranging from electronics to optics, sensors, and biodevices.

There are various methods of producing graphene, for example, micromechanical peeling, chemical stripping, silicon carbide epitaxial growth, and chemical vapour deposition. The chemical vapour deposition is a widely opted method as the graphene quality produced by this method is comparatively higher than with other methods. However, growth rates are rather small with existing chemical vapour deposition methods, as they are carried out under low-pressure conditions, such as 0.0001 bar. In the existing chemical vapour deposition methods that are used to form graphene on top of a substrate, graphene growth is limited to small clusters or islands. Further, these chemical vapour deposition methods are not suitable for manufacturing graphene sheets having uniform thickness. The graphene sheets with non-uniform surfaces show variation in properties such as resistance, transmittance and hence become unsuitable for use in electronic applications.

Graphene sheets with large lateral size are desirable for use in many opto-electronic and biomedical applications and the demand for graphene sheets is increasing due to its industrial applicability across multiple applications. Existing approaches lack the capability to continuously produce large uniform sheets of graphene without deviations with respect to physical and electrical properties. Further, the existing approaches are not capable of large-scale production of graphene materials due to the slow growth rate of graphene on the substrate.

Therefore, in light of the foregoing challenges present in the art, there exists a need to address and preferably to overcome the aforementioned drawbacks in existing known approaches for manufacturing a large uniform layer of graphene on a substrate using chemical vapour deposition without variations in the physical and electrical properties of the graphene layer.

### SUMMARY

The present disclosure seeks to provide a process and system for manufacturing a graphene layer on a substrate. In an aspect, an embodiment of the present disclosure provides a process for manufacturing a graphene layer on a substrate, comprising the steps of
providing a gaseous environment for chemical vapour deposition with a pressure in a range of 0.5-2 bar, the gaseous environment having a composition of
   hydrogen gas,
   a first gas, wherein the first gas is inert in chemical vapour deposition conditions, and
   a second gas,
   wherein a gas ratio of hydrogen/second gas is from 1:1 to 100:1, partial pressure of the first gas is 75-90% of the total gas pressure and partial pressure of a mixture of the second gas and hydrogen gas is 10-25% of the total gas pressure,
pre-heating the substrate to a first temperature;
heating a first area of the substrate to a second temperature which is higher than the first temperature, wherein the first area has a first width that is less than 1 millimetre;
allowing a graphene layer to form on the first area by chemical vapour deposition;
allowing the first area to cool down;
heating a second area of the substrate to the second temperature, wherein the second area is adjacent to the first area;
allowing a graphene layer to form on the second area by chemical vapour deposition, wherein the second area has a second width that is less than 1 mm; and
allowing the second area to cool down.

In another aspect, an embodiment of the present disclosure provides a system for manufacturing a graphene layer on a substrate, the system comprising
a growth chamber for providing a gaseous environment for chemical vapour deposition with a pressure range of 0.5-2 bar,
a first roll for the substrate prior to coating,
a first heating means for heating the uncoated substrate to a first temperature;
a second heating means for heating an area of the substrate in a reaction zone to a second temperature that is higher than the first temperature, for forming a graphene layer on the area of the substrate by chemical vapour deposition, wherein the area has a width that is less than 1 mm,
a second roll for receiving the substrate coated with the graphene layer, and
means for transferring the substrate from the first roll to the reaction zone and from the reaction zone to the second roll.

Embodiments of the present disclosure substantially eliminate, or at least partially address, the aforementioned drawbacks in existing known approaches for manufacturing a large uniform layer of graphene on a substrate using the chemical vapour deposition without variations in the physical and electrical properties of the graphene layer.

Additional aspects, advantages, features and objects of the present disclosure would be made apparent from the drawings and the detailed description of the illustrative embodiments construed in conjunction with the appended claims that follow.

It will be appreciated that features of the present disclosure are susceptible to being combined in various combinations without departing from the scope of the present disclosure as defined by the appended claims.

### BRIEF DESCRIPTION OF THE DRAWINGS

The summary above, as well as the following detailed description of illustrative embodiments, is better understood when read in conjunction with the appended drawings. For the purpose of illustrating the present disclosure, exemplary constructions of the disclosure are shown in the drawings. However, the present disclosure is not limited to specific methods and instrumentalities disclosed herein. Moreover, those in the art will understand that the drawings are not to scale. Wherever possible, like elements have been indicated by identical numbers.

Embodiments of the present disclosure will now be described, by way of example only, with reference to the following diagrams wherein:

FIG. 1 is a schematic illustration of a system, in accordance with an embodiment of the present disclosure;

FIG. 2 is a schematic illustration of a system that forms a graphene layer on a substrate, in accordance with an embodiment of the present disclosure;

FIG. 3 is a flow diagram that illustrates steps of a process for (of) manufacturing a graphene layer on a substrate, in accordance with an embodiment of the present disclosure and

FIGS. 4A and 4B are a schematic illustration of steps of forming a graphene layer on a substrate, in accordance with an embodiment of the present disclosure.

In the accompanying drawings, an underlined number is employed to represent an item over which the underlined number is positioned or an item to which the underlined number is adjacent. A non-underlined number relates to an item identified by a line linking the non-underlined number to the item. When a number is non-underlined and accompanied by an associated arrow, the non-underlined number is used to identify a general item at which the arrow is pointing.

### DETAILED DESCRIPTION OF EMBODIMENTS

The following detailed description illustrates embodiments of the present disclosure and ways in which they can be implemented. Although some modes of carrying out the present disclosure have been disclosed, those skilled in the art would recognize that other embodiments for carrying out or practicing the present disclosure are also possible.

In an aspect, an embodiment of the present disclosure provides a process for manufacturing a graphene layer on a substrate, comprising the steps of
providing a gaseous environment for chemical vapour deposition with a pressure in a range of 0.5-2 bar, the gaseous environment having a composition of
   hydrogen gas,
   a first gas, wherein the first gas is inert in chemical vapour deposition conditions, and
   a second gas,
   wherein a gas ratio of hydrogen/second gas is from 1:1 to 100:1, partial pressure of the first gas is 75-90% of the total gas pressure and partial pressure of a mixture of the second gas and hydrogen gas is 10-25% of the total gas pressure,
pre-heating the substrate to a first temperature;
heating a first area of the substrate to a second temperature which is higher than the first temperature, wherein the first area has a first width that is less than 1 millimetre;
allowing a graphene layer to form on the first area by chemical vapour deposition;
allowing the first area to cool down;
heating a second area of the substrate to the second temperature, wherein the second area is adjacent to the first area;
allowing a graphene layer to form on the second area by chemical vapour deposition, wherein the second area has a second width that is less than 1 mm; and
allowing the second area to cool down.

The process produces a uniform graphene layer on the substrate. The graphene layer that is manufactured using the present process has uniform physical properties such as high electric conductivity, high tensile strength and high surface area to volume ratio of graphene. Indeed, while the above process description only mentions a first and a second area, the process is typically repeated for n times, until a sufficient size of coated substrate is achieved. The present process is based on growth of the graphene layer on areas of small dimensions at a time, i.e. in areas having a width of less than 1 mm, which may also be defined as “line-by-line”-growing of graphene. This enables performing the chemical vapour deposition in the pressure range of 0.5-2 bar, which is several orders of magnitude higher than previous methods using chemical vapour deposition that are carried under low-pressure conditions such as 0.0001 bar. The pressure range of 0.5-2 bar increases the growth rate of the graphene layer on the substrate. The term “uniform” means having a uniformity variation of less than +/−10%, and optionally having a uniformity variation of less than +/−3% in the physical properties of the graphene layer.

The first gas is inert in chemical vapour deposition conditions. The first gas may act as a co-catalyst by increasing the rate of deposition of graphene on the substrate by enhancing the surface reaction rate. The partial pressure conditions of the first gas and the second gas may be chosen to produce a graphene layer with a desired nucleation density and domain size suitable for a variety of applications. The graphene layer that is manufactured by the present process can be used for manufacturing transparent electrodes that can be employed in opto-electronic devices, electric vehicles, bio-medical devices etc.

The gaseous environment has a composition of at least three different gas, namely hydrogen gas, an inert first gas and a second gas which forms a source of carbon. Some examples of the second gas are given below. In the composition, a gas ratio of hydrogen/second gas is from 1:1 to 100:1, partial pressure of the first gas is 75-90% of the total gas pressure and partial pressure of a mixture of the second gas and hydrogen gas is 10-25% of the total gas pressure.

Indeed, the partial pressure of the first gas can be from 75, 77, 79, 80, 83, 85, or 88% of the total gas pressure up to 79, 80, 83, 85, 88 or 90% of the total gas pressure. The partial pressure of the mixture of the second gas and hydrogen gas can be from 10, 12, 14, 16, 17, 18 20, 21, 22 or 23% of the total gas pressure up to 12, 14, 16, 17, 18, 20, 21, 22, 23, 24 or 25% of the total gas pressure. The gas ratio of hydrogen/second gas can be from 1:1, 2:1, 5:1, 10:1, 15:1, 20:1, 25:1, 30:1, 35:1, 40:1, 45:1, 50:1, 55:1, 60:1, 65:1, 70:1, 75:1 or 80:1 up to 5:1, 10:1, 15:1, 20:1, 25:1, 30:1, 35:1, 40:1, 45:1, 50:1, 55:1, 60:1, 65:1, 70:1, 75:1, 80:1, 85:1, 90:1, 95:1 or 100:1. In another example, the partial pressure of hydrogen gas can be 7.5-17% of the total gas pressure, i.e. for example from 7.5, 8, 9, 10, 11, 12, 13, 14 or 15% up to 9, 10, 11, 12, 13, 14, 15, 16 or 17% of the total gas pressure. Similarly, the partial pressure of the second gas can be 2.5-8% of the total gas pressure, i.e. from 2.5, 3, 4, 5, 6 or 7% up to 4, 5, 6, 7 or 8% of the total gas pressure. The partial pressures are chosen to improve the growth rate of the graphene layer and help with formation of a hexagonal shape of graphene grains without irregularities.

One particularly suitable combination of parameters, when using a laser of blue light with 15 W and 450 nm are 800-870° C. for the first temperature, less than 1100° C. for the second temperature, laser scanning speed of 1.4 cm/s to 2 cm/s, and partial pressures of gases 13-15% for H₂, 4-6% for the second gas and 79-83% for the first gas of total gas pressures.

The “line by line” growth of graphene, starting with the first area, and then the adjacent second area, and further, with both the first area and the second area having a width of <1 mm on the substrate enables growing a large layer of graphene at a rapid rate. While a second (and further) area is being heated a second temperature and thus the graphene layer grown on it, the first (and preceding) are is allowed to cool down, i.e. the process is continuous. It is of course also possible to run the process in an intermittent manner, but continuous process is preferred for its efficiency.

The cooling process after the formation of the graphene layer on the first area on the substrate facilitates etching of weakly formed carbon bonds and thus helps to maintain the integrity of the formed graphene layer. The cooling may be carried out by simply allowing the coated substrate to cool down or it may be accelerated and/or regulated using means for cooling, such as a fan.

In an embodiment, the second gas is selected from a group consisting of alkane, aromatic, alkylene, ketone, ether, ester, alcohol, aldehyde, phenol and organic acid. In an embodiment, the second gas has a carbon source and contains carbon. Thus, according to an embodiment, the second gas is a carbon source gas selected from a group consisting of methane, ethane, propane, ethylene, propylene, acetylene, propyne, benzene, naphthalene and anthracene. The carbon source gas decomposes in the growth chamber under the chemical vapour deposition reaction conditions to produce pure carbon atoms for formation of the graphene layer.

According to another embodiment, the first gas is selected from a group consisting of hydrogen, argon, xenon, helium and nitrogen. The first gas may act as a co-catalyst for forming surface bound carbon and it may also be used to control a grain shape and dimensions of the graphene by etching away weak carbon bonds.

According to yet another embodiment, the first temperature is in a range of 500° C. to 900° C. The substrate is preheated at the first temperature and the preheating prepares the substrate for graphene formation. The first temperature can be from 500, 520, 550, 570, 600, 620, 650, 680, 700, 720, 750, 780, 800, 820, 850 or 870° C. up to 550, 570, 600, 620, 650, 680, 700, 720, 750, 780, 800, 820, 850, 870, 880 or 900° C.

According to yet another embodiment, the second temperature is in a range of 750° C. to 1200° C., provided that even when the first temperature is between 750-900° C., the second temperature is higher than the first temperature. The second temperature, which is higher than the first temperature, causes formation of graphene by chemical vapour deposition. The second temperature can be from 750, 770, 800, 820, 850, 880, 900, 920, 950, 970, 1000, 1050, 1080, 1100 or 1120° C. up to 800, 820, 850, 880, 950, 970, 1000, 1050, 1080, 1100, 1020, 1150, 1180 or 1200° C.

Indeed, the second temperature T2 is higher than the first temperature T1, typically of at least 20 or 30° C. Indeed, the first temperature T1 is selected such that the conditions for formation of graphene on the substrate are almost achieved (the conditions depend, in addition to the temperature, also of the partial pressures of the gases etc.). After pre-heating, the substrate is heated to the second temperature T2, in which graphene is formed on the substrate.

According to an embodiment, the substrate is selected from a group consisting of nickel, cobalt, iron, platinum, gold, aluminium, chromium, copper, magnesium, manganese, molybdenum, rhodium, silicon, tantalum, titanium, tungsten, uranium, vanadium, zirconium, brass, bronze and stainless steel. The substrate can be in any suitable form, but is preferably in sheet-like form and most preferably has a thickness of 0.01-0.5 mm.

According to yet another embodiment, the substrate is in the form of a continuous strip. A continuous strip of coated substrate is formed when the process is applied on the first area and thereafter repeated on each adjacent area in turn continuously. In one embodiment, the first area and each adjacent area are in the form of a rectangle having a length that depends on a width of the substrate, and having a width less than 1 mm. The width of the substrate can be arbitrary limited basically by dimensions of the growth chamber. As an example, the width of the substrate can be selected from any suitable range from say 1 cm to 10 cm, 50 cm, 100 cm or more. As an example, first area can be thus for example length of 50 cm and width of less than 1 mm. In another embodiment, the first area and each adjacent area are circular in shape, having a diameter less than 1 mm.

According to yet another embodiment, the first width (W1) of the first area of the substrate and the second width (W2) of the second area of the substrate are essentially identical. The first and second widths can also be independently selected from any suitable range below 1 mm, such as from 0.001, 0.005, 0.01, 0.025, 0.05, 0.07, 0.1, 0.2, 0.3, 0.4, 0.5, 0.6, 0.7 or 0.8 mm up to 0.01, 0.025, 0.05, 0.07, 0.1, 0.2, 0.3, 0.4, 0.5, 0.6, 0.7, 0.8, 0.9 or 0.95 mm.

In an embodiment, the substrate is cleaned at a temperature in a range of 900° C. to 1100° C. prior to subjecting it to chemical vapour deposition. In another embodiment, the substrate is cleaned at a temperature that is greater than 1100° C.

In another aspect, an embodiment of the present disclosure provides a system for manufacturing a graphene layer on a substrate, the system comprising
a growth chamber for providing a gaseous environment for chemical vapour deposition with a pressure range of 0.5-2 bar,
a first roll for the substrate prior to coating,
a first heating means for heating the uncoated substrate to a first temperature;
a second heating means for heating an area of the substrate in a reaction zone to a second temperature that is higher than the first temperature, for forming a graphene layer on the area of the substrate by chemical vapour deposition, wherein the area has a width that is less than 1 mm,
a second roll for receiving the substrate coated with the graphene layer, and
means for transferring the substrate from the first roll to the reaction zone and from the reaction zone to the second roll.

The same embodiments and variants as described above for the process apply mutatis mutandis to the system.

The substrate acts as a catalyst for manufacturing the graphene layer. The catalytic substrate helps in growing continuous layers of high-quality graphene over a large area due to its catalytic activity towards hydrocarbon gas sources. The graphene layer is thus formed on a top of the substrate, when the gas mixture interacts with the upper surface of the catalytic substrate.

According to an embodiment, the first heating means and the second heating means are independently selected from a group consisting of resistive, electromagnetic and inductive heating means. In one embodiment, the substrate is preheated by applying a current between the first roll and the second roll, i.e. the first heating means is based on electricity. In yet another embodiment, the first heating means and the second heating means are independently selected from an induction heater, a blue light laser heater and an infrared laser heater. In one embodiment, the heating means thus comprises an infrared laser source. In another embodiment, the heat is generated from a laser device, which emits an infrared beam. In yet another embodiment, a blue laser at 450 nm is used as the second heating means.

In an embodiment, the heating means is provided outside the growth chamber to improve the safety of the system. The heat from the heating means may be transmitted through fibre optics such as fibre optic cables to the growth chamber to heat the substrate. Alternatively, heat from the heating means may be provided through a window.

According to an embodiment, the system further comprises means for cooling down the substrate coated with the graphene layer. Such means can be any suitable cooling means such as a fan or a heat exchanger.

In an embodiment, the first area may be in the form of rectangle that has a length that depends on a width of the substrate. The graphene layer having a width of not exceeding 1 mm leads to small dimension growth, which enables the use of pressure in a range of 0.5 bar to 2 bar and improves the growth rate of the graphene layer. The graphene layer is thus formed “line by line” to form a large uniform layer of graphene. In another embodiment, the first area and the second area of the substrate are dimensioned to be in any arbitrary form, and may not be restricted to specific well-defined geometric shapes like rectangles or circles.

As an example of the “line by line” growth of a graphene layer is grown by scanning a surface of the substrate with a laser light to heat a first area of the substrate to the second temperature in a controlled manner. As the surface of the substrate is heated by the laser, the carbon source gas decomposes in the area heated by the laser. Indeed, the chemical vapour deposition reaction conditions are formed in said heated area to produce pure carbon atoms for formation of the graphene layer. In an embodiment an infrared laser or a blue light laser is used to heat the surface. A beam of light is preferably directed to the surface from the same side as the growth takes place. The scanning can be continuous scanning of the surface to form in the end of the process a large uniform area. During the growth process the substrate can be configured to move during the scanning. Alternatively, the substrate can be stationary and the laser can be configured to scan the surface. Further the substrate can be configured to move and the laser can be configured to scan at the same time. Alternatively to scanning the laser beam can be arranged as a stripe having dimensioned as width of less than 1 mm but length for example same as the width of the substrate or target width of the graphene layer.

Alternatively to line-by-line growth the heating can be arranged as dots i.e. dot by dot growth. Each dot would be next to adjacent previous dot to enable growing of a large area.

In an embodiment, the substrate is provided uncoated from the first roll and the substrate containing the graphene layer, i.e. the coated substrate is collected by the second roll. The substrate is thus typically arranged roll to roll in a graphene deposition region in the growth chamber, which extends transversely along the moving direction of the substrate from the first roll to the second roll. The first roll and the second roll may be rotated in a counter clockwise direction.

In an embodiment, the first area or the second area of the substrate to be heated is moved using the first roller to change the area that is heated and its position with respect to the second heating means, which is kept stationary. In another embodiment, the second heating means is arranged to move while the substrate is kept stationary.

In an embodiment, the system comprises multiple chambers through which the substrate moves to produce the graphene layer. Accordingly, the catalytic substrate is provided from a first chamber into a second chamber. The second chamber, which is the chemical vapor deposition chamber preferably comprises an inlet for continuous in-flow of the catalytic substrate from the first chamber and outlet for continuous exit of the catalytic substrate with a newly formed graphene layer. The catalytic substrate with the newly formed graphene layer is collected in a third chamber.

In an embodiment, the system comprises a cooling chamber containing only the inert gases that are inert in chemical vapour deposition conditions, which do not contain carbon, for cooling the substrate after the formation of the graphene layer on the substrate.

In an embodiment, the system further comprises a pre-chamber for cleaning and pre-heating the substrate. The system may also comprise more than two rolls (such as three, four, five or six rolls) that electrically feed the substrate into the growth chamber. It is thus possible to feed for example two, three or four parallel strips of substrate and to coat them simultaneously.

The advantages of the present system are thus identical to those disclosed above in connection with the present process and the embodiments listed above in connection with the present process apply mutatis mutandis to the present system.

### Experimental Part

Graphene layers were manufactured as follows.

The total reactor pressure was kept at normal atmospheric pressure, i.e. about 1,013 bar. The width of the substrate (made of copper) on which the graphene layer was manufactured was 15 mm in all tests and the thickness of the substrate was 0.01 mm. Different first temperatures, i.e. the pre-heating temperatures T1 were tested, ranging from 550° C. up to 870° C., as shown in Table 1 below. Pre-heating was carried out using a heating element consisting of a resistively heated resistor arranged inside a tube made of quartz, and the substrate passes over the tube. Heating to the second temperature T2 was performed by scanning a laser beam across the substrate. The laser used was a blue laser of 15 W at 450 nm. The laser beam was focused on an area of under 1 mm² (and width of less than 1 mm).

Accurate temperature for T2 could not be measured due to the small size of the scanned area at any given moment. However, T2 was under 1085° C. in all tests, as the copper substrate did not melt. The effective temperature of T2 is affected, in addition to the nature and focusing of the laser, by the scanning speed of the laser. Laser scanning speeds from 1.2 cm/s up to 4.5 cm/s were tested (details in Table 1).

Furthermore, different partial gas pressures were tested. Partial gas pressure of H₂ ranging from 8% to 15% of the total gas pressure, and the carbon source gas (i.e. second gas) pressures tested ranged from 0.7% to 6% of the total gas pressure. Details are shown in Table 1. The carbon source gas was methane and the inert gas was argon.

TABLE 1

| | | | Gas concentration in percent | | | | Total |
|---|---|---|---|---|---|---|---|
| | | | | Carbon | | Scanning | pres- |
| | T1 | T2 | | source | Inert | speed | sure |
| Test | (° C.) | (° C.) | H₂ | gas | gas | (cm/s) | (atm) |
| 1 | 550 | <1085 | 13 | 0.7 | 86.3 | 1.2 | 1 |
| 2 | 650 | <1085 | 8 | 2 | 90 | 1.5 | 1 |
| 3 | 650 | <1085 | 13 | 2 | 85 | 3 | 1 |
| 4 | 650 | <1085 | 13 | 4 | 83 | 4 | 1 |
| 5 | 750 | <1085 | 15 | 4 | 81 | 1.5 | 1 |
| 6 | 750 | <1085 | 13 | 6 | 81 | 4 | 1 |
| 7 | 800 | <1085 | 13 | 2 | 85 | 2 | 1 |
| 8 | 800 | <1085 | 13 | 2 | 85 | 3 | 1 |
| 9 | 800 | <1085 | 13 | 2 | 85 | 4.5 | 1 |
| 10 | 800 | <1085 | 15 | 4 | 81 | 1.5 | 1 |
| 11 | 820 | <1085 | 13 | 4 | 83 | 1.5 | 1 |
| 12 | 870 | <1085 | 15 | 6 | 79 | 2 | 1 |
| 13 | 870 | <1085 | 15 | 6 | 79 | 4.5 | 1 |
| 14 | 870 | <1085 | 13 | 2 | 85 | 1.5 | 1 |

Best parameters for the process were determined to be 800-870° C. for T1, laser scanning speed of 1.4 cm/s to 2 cm/s, and partial pressures of gases 13-15% for H₂, 4-6% for carbon source gas (second gas) and 79-83% inert gas (first gas) of total gas pressures. These are the tests 10, 11 and 12 above.

With the parameters in these ranges, areas were formed on the substrate which have a high likelihood of being graphene. This conclusion was reached by testing the oxidisation of the substrate as well as observing a higher contact angle in a sessile drop test in the samples compared to control samples. The sessile drop test, used to assess the hydrophobicity of materials, was carried out as explained in “Contact angle measurement of free-standing square-millimeter single-layer graphene”, Prydatko et al. Nature Communications, vol. 9, article number 4185 (2018). Control samples were oxidised copper substrates and substrates covered by graphene were not oxidised.

Samples produced with parameters out of the ranges mentioned above did not have evidence for presence of graphene, i.e. no graphene could be manufactured in these conditions.

### DETAILED DESCRIPTION OF THE DRAWINGS

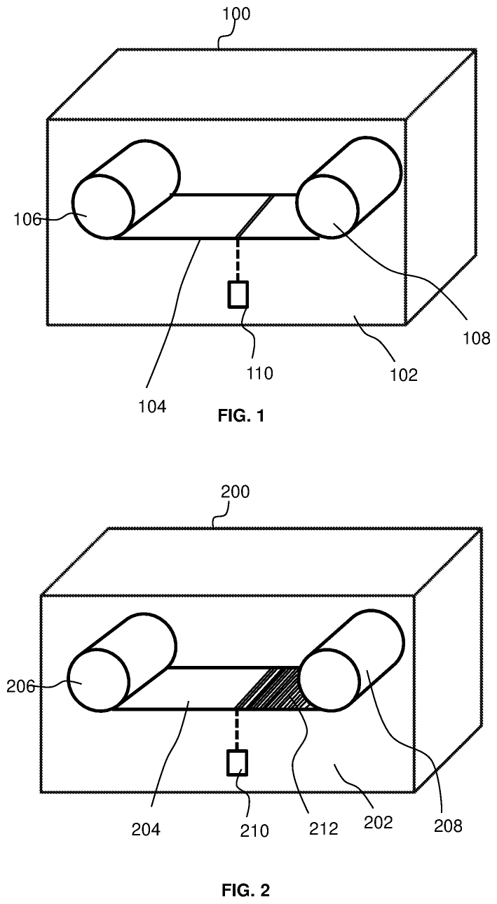

Referring to FIG. 1, there is shown a schematic illustration of a system 100, in accordance with an embodiment of the present disclosure. As shown, the system 100 includes a growth chamber 102, a substrate 104, a first roll 106, a second roll 108, and a heat source 110 as second heating means.

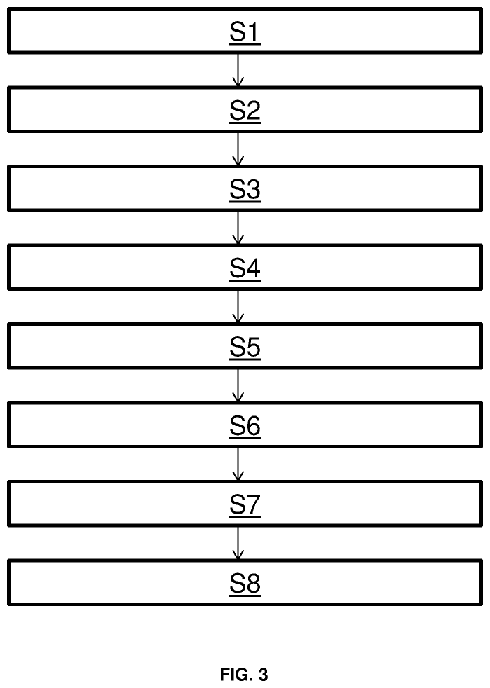

Referring to FIG. 2, there is shown a schematic illustration of a system 200 that forms a graphene layer 212 on a substrate 204, in accordance with an embodiment of the present disclosure. As shown, the system 200 includes a growth chamber 202, the substrate 204, a first roll 206, a second roll 208 and a heat source 210 as second heating means.

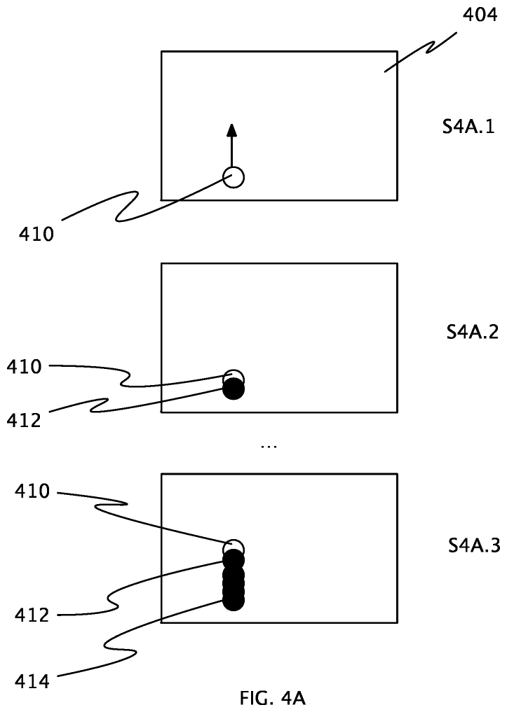

Referring to FIG. 3, there is shown a flow diagram that illustrates steps of a process for manufacturing a graphene layer on a substrate, in accordance with an embodiment of the present disclosure. At a step S1, a gaseous environment for chemical vapour deposition with a pressure range of 0.5-2 bar is provided. The gaseous environment has a composition of a first gas and a second gas. The first gas is inert in the chemical vapour deposition conditions. At a step S2, the substrate is pre-heated to a first temperature. At a step S3, a first area of the substrate is heated to a second temperature which is higher than the first temperature. The first area has a first width (W1) that is less than 1 mm. At a step S4, a graphene layer is allowed to form on the first area by the chemical vapour deposition. At a step S5, the first area containing the graphene layer is allowed to cool down. At a step S6, a second area, adjacent to the first area, of the substrate is heated to the second temperature. At a step S7, a graphene layer is allowed to form on the second area by the chemical vapour deposition. The second area has a second width (W2) that is less than 1 mm. At a step S8, the second area containing the graphene layer is allowed to cool down. Steps S5 and S6, for example, can be carried out simultaneously, as can the further steps, i.e. while the first area is cooling down, a second area can be coated.

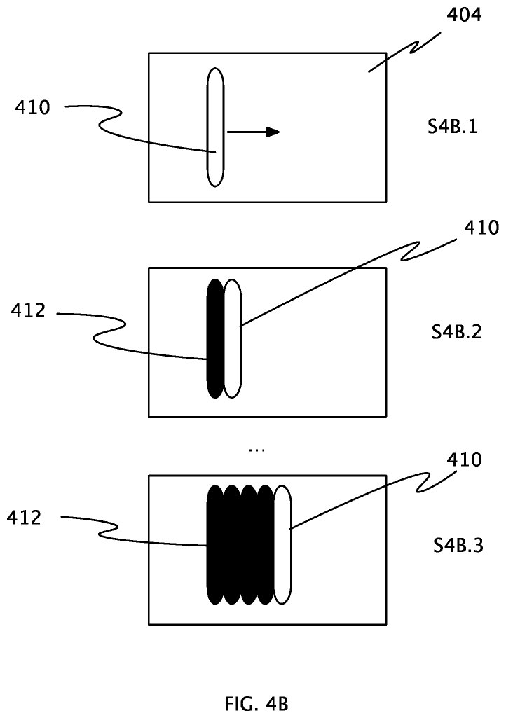

FIG. 4A is an example illustrating forming a graphene layer in top of a substrate 404. Step S4A.1 illustrates a starting of the growth process. A beam of laser 410 is used to heat the substrate 404 to a second temperature. Diameter of the laser light beam 410 is configured to be less than 1 mm. Graphene starts to form in the heated area immediately. The beam of laser is configured to move to direction indicated with an arrow with a constant speed. The speed is selected to give sufficient time for the graphene growth. The growth rate depends on used substrate and partial pressures. Step S4A.2 illustrates a moment of time wherein the laser beam 410 has moved up (in respect to the figure) slightly (for example 0.5 mm). Graphene 412 has formed in the area heated during the step S4A.1. Step S4A.3 illustrates a moment of time wherein the laser beam 410 has moved up for example 5 mm. A graphene strip 414 of about 1 mm×5 mm has been formed.

FIG. 4B is an illustration of a setup wherein the beam of laser 410 is configured to be in a form of a stripe. In example figure (S4B.1) the stripe is less than 1 mm wide and length is 10 mm. The laser stripe is configured to move to direction indicated with an arrow with a constant speed. The speed is selected to give sufficient time for the graphene growth. The growth rate depends on used substrate and partial pressures. In step S4B.2 the stripe 410 has moved 1 mm and a graphene 412 is formed in area heated with the laser stripe during S4B.1. Step S5B.3 illustrates a moment of time after the laser stripe 410 has moved 5 mm. Thus, a uniform layer of graphene of 4×10 mm has been formed. Alternatively, a first area of the surface (i.e. surface of the first stripe 410) is heated (step S4B.1) to second temperature, graphene is grown in the first area and it is cooled down thus forming a graphene layer 412. After that a second area (a stripe 410 in S4B.2 adjacent to the first area) is heated to a second temperature, graphene is grown in the second area.

Modifications to embodiments of the present disclosure described in the foregoing are possible without departing from the scope of the present disclosure as defined by the accompanying claims. Expressions such as “including”, “comprising”, “incorporating”, “have”, “is” used to describe and claim the present disclosure are intended to be construed in a non-exclusive manner, namely allowing for items, components or elements not explicitly described also to be present. Expressions such as “may” and “can” are used to indicate optional features, unless indicated otherwise in the foregoing. Reference to the singular is also to be construed to relate to the plural.

1. A manufacturing process for manufacturing a graphene layer on a substrate, comprising:
providing a gaseous environment for chemical vapour deposition with a pressure in a range of 0.5-2 bar, the gaseous environment having a composition of:
hydrogen gas,
a first gas, wherein the first gas is inert in chemical vapour deposition conditions, and
a second gas,
wherein a gas ratio of hydrogen/second gas is from 1:1 to 100:1, partial pressure of the first gas is 75-90% of the total gas pressure and partial pressure of a mixture of the second gas and hydrogen gas is 10-25% of the total gas pressure,
pre-heating the substrate to a first temperature;
heating a first area of the substrate to a second temperature which is higher than the first temperature, wherein the first area has a first width that is less than 1 millimetre;
allowing a graphene layer to form on the first area by chemical vapour deposition;
allowing the first area to cool down;
heating a second area of the substrate to the second temperature, wherein the second area is adjacent to the first area;
allowing a graphene layer to form on the second area by chemical vapour deposition, wherein the second area has a second width that is less than 1 mm; and
allowing the second area to cool down.

2. The manufacturing process according to claim 1, wherein the second gas is a carbon source gas that is selected from a group consisting of methane, ethane, propane, ethylene, propylene, acetylene, propyne, benzene, naphthalene and anthracene.

3. The manufacturing process according to claim 1, wherein the first gas is selected from a group consisting of argon, xenon, helium and nitrogen.

4. The manufacturing process according to claim 1, wherein the first temperature is in a range of 500° C. to 900° C.

5. The manufacturing process according to claim 1, wherein the second temperature is in a range of 750° C. to 1200° C.

6. The manufacturing process according to claim 1, wherein the substrate is selected from a group consisting of nickel, cobalt, iron, platinum, gold, aluminium, chromium, copper, magnesium, manganese, molybdenum, rhodium, silicon, tantalum, titanium, tungsten, uranium, vanadium, zirconium, brass, bronze and stainless steel.

7. The manufacturing process according to claim 1, wherein the first heating is carried out by resistive heating.

8. The manufacturing process according to claim 1, wherein the first width and the second width are essentially identical.

9. The manufacturing process according to claim 1, wherein the substrate is in the form of a continuous strip.

10. A system for manufacturing a graphene layer on a substrate, the system comprising
a growth chamber for providing a gaseous environment for chemical vapour deposition with a pressure range of 0.5-2 bar,
a first roll for the substrate prior to coating,
a first heating means for heating the uncoated substrate to a first temperature;
a second heating means for heating an area of the substrate in a reaction zone to a second temperature that is higher than the first temperature, for forming a graphene layer on the area of the substrate by chemical vapour deposition, wherein the area has a width that is less than 1 mm,
a second roll for receiving the substrate coated with the graphene layer, and
means for transferring the substrate from the first roll to the reaction zone and from the reaction zone to the second roll.

11. The system according to claim 10, further comprising means for cooling down the substrate coated with the graphene layer.

12. The system according to claim 10, wherein the first heating means and the second heating means are independently selected from a group consisting of resistive, electromagnetic and inductive heating means.

13. The system according to claim 12, wherein the first heating means and the second heating means are independently selected from a resistive heater, a blue laser heater and an infrared laser heater.
